(19) United States
(12) Patent Application Publication
(10) Pub. No.: US 2024/0373658 A1
(43) Pub. Date: Nov. 7, 2024

(54) OPTICAL SENSOR

(71) Applicant: Japan Display Inc., Tokyo (JP)

(72) Inventor: Motochika YUKAWA, Tokyo (JP)

(21) Appl. No.: 18/776,352

(22) Filed: Jul. 18, 2024

Related U.S. Application Data
(63) Continuation of application No. PCT/JP2022/042870, filed on Nov. 18, 2022.

(30) Foreign Application Priority Data
Jan. 21, 2022 (JP) 2022-007954

(51) Int. Cl. H10K 30/85; H10K 30/86; H10K 39/30

(52) U.S. Cl. CPC H10K 30/85; H10K 30/86; H10K 39/30

(57) ABSTRACT

An optical sensor includes a plurality of lower electrodes adjacent to one another, an organic material layer that includes a lower carrier transport layer including a plurality of first electrode covering parts each covering at least an upper surface of corresponding one of the plurality of lower electrodes, and a carrier mobility reducing part that is provided in at least a part of an area between the adjacent first electrode covering parts so as to reduce carrier mobility of the adjacent first electrode covering parts.

### CROSS-REFERENCE TO RELATED APPLICATION

The present application is Bypass Continuation of International Application No. PCT/JP2022/042870, filed on Nov. 18, 2022, which claims priority from Japanese application No. 2022-007954 filed on Jan. 21, 2022, the content of which is hereby incorporated by reference into this application.

### BACKGROUND OF THE INVENTION

### 1. Field of the Invention

The present invention relates to an optical sensor.

### 2. Description of the Related Art

In recent years, an optical sensor in which organic photodiodes (OPD) are arranged on a substrate has been known. Such an optical sensor is used as a biometric sensor for detecting biometric information, such as a fingerprint and a vein.

The optical sensor using the OPD includes a thin film transistor and an organic photoelectric conversion layer formed on the substrate. The organic photoelectric conversion layer is formed of an organic material layer, which has a plurality of layers including an organic light-receiving layer, disposed between the upper electrode and the lower electrode. For example, as disclosed in JP2021-125691A and JP2021-57422A, the organic material layer may be commonly provided on a plurality of lower electrodes.

If a highly conductive carrier transport layer (e.g., hole transporting layer) among the organic material layers is commonly provided on a plurality of lower electrodes in the optical sensor using the OPD, a leakage current is likely to be generated between adjacent lower electrodes. Such a leakage current can be remarkably generated as the density of the lower electrode increases with the higher resolution and the resistance of the carrier transport layer decreases.

One or more embodiments of the present invention have been conceived in view of the above, and an object thereof is to provide an optical sensor in which a leakage current generated between adjacent lower electrodes via a carrier transport layer is reduced.

### Solution to Problem

An optical sensor according to one aspect of the present invention includes a plurality of lower electrodes adjacent to one another, an organic material layer that includes a lower carrier transport layer including a plurality of first electrode covering parts each covering at least an upper surface of corresponding one of the plurality of lower electrodes, and a carrier mobility reducing part that is provided in at least a part of an area between the adjacent first electrode covering parts so as to reduce carrier mobility of the adjacent first electrode covering parts.

According to one aspect of the present invention, a leakage current generated between adjacent lower electrodes via a carrier transport layer can be reduced.

### BRIEF DESCRIPTION OF THE DRAWINGS

FIG. 1 is a schematic plan view of an optical sensor according to an embodiment of the present invention;

FIG. 2 is a block diagram showing an example of a configuration of the optical sensor according to the embodiment of the present invention;

FIG. 3 is an enlarged plan view of an area A surrounded by the broken line in FIG. 1;

FIG. 4 is a partial sectional view of the optical sensor taken along the line IV-IV of FIG. 1 according to the first embodiment;

FIG. 5 is an enlarged partial sectional view of the OPL and its surroundings shown in FIG. 4;

FIG. 6A is a schematic cross section showing a process of forming a carrier mobility reducing part 250 according to the first embodiment;

FIG. 6B is a table showing an example of laser conditions to be used when the carrier mobility reducing part 250 according to the first embodiment is formed;

FIG. 7A is another example of an enlarged plan view of an area A enclosed by the broken line in FIG. 1;

FIG. 7B is a schematic diagram illustrating an example of a film forming mask used in a process of forming the carrier mobility reducing part 250;

FIG. 8 is a partial sectional view of the optical sensor taken along the line IV-IV of FIG. 1 according to the second embodiment;

FIG. 9 is an enlarged partial sectional view of the OPL and its surroundings shown in FIG. 8;

FIG. 10A is a schematic cross section showing a process of forming a carrier mobility reducing part 250 according to the second embodiment; and

FIG. 10B is a table showing an example of laser conditions to be used when the carrier mobility reducing part 250 according to the second embodiment is formed.

### DETAILED DESCRIPTION OF THE INVENTION

Embodiments of the present invention will be described below in detail with reference to the accompanying drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the detailed description of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

### First Embodiment

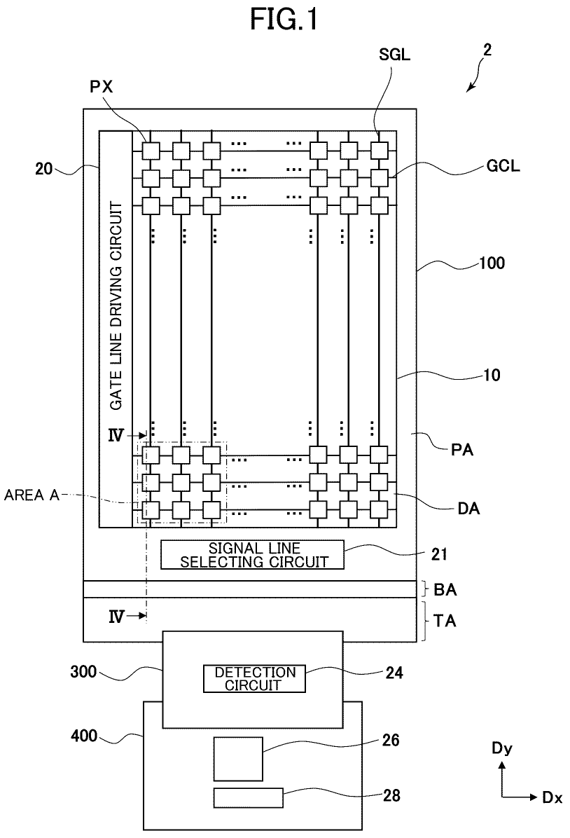

FIG. 1 is a schematic plan view of an optical sensor according to an embodiment of the present invention. As shown in FIG. 1, an optical sensor 2 includes a resin substrate 100, a sensor unit 10, a gate line driving circuit 20, a signal line selecting circuit 21, a detection circuit 24, a control circuit 26, and a power supply circuit 28.

The resin substrate 100 is electrically connected to a control substrate 400 via a flexible printed board 300. The flexible printed board 300 includes the detection circuit 24. The control substrate 400 includes the control circuit 26 and the power supply circuit 28. The control circuit 26 is a field programmable gate array (FPGA), for example. The control circuit 26 supplies control signals to the sensor unit 10, the gate line driving circuit 20, and the signal line selecting circuit 21 so as to control the detection operation of the sensor unit 10. The power supply circuit 28 supplies a power supply voltage to the sensor unit 10, the gate line driving circuit 20, and the signal line selecting circuit 21.

The resin substrate 100 includes a detection area DA and a frame area PA. The detection area DA is an area in which the sensor unit 10 is provided. The frame area PA is an area outside the detection area DA where the sensor unit 10 is not provided. In other words, the frame area PA is an area between the end portion of the detection area DA and the end portion of the resin substrate 100.

The frame area PA has a bending area BA and a terminal area TA. The bending area BA and the terminal area TA are provided at one end of the frame area. Wires connected to the detection area DA are disposed in the bending area BA and the terminal area TA. The resin substrate 100 and the flexible printed board 300 are connected to each other in the terminal area TA.

The sensor unit 10 includes a plurality of pixels PX. The pixels PX are disposed in a matrix in the detection area DA. The pixels PX are photodiodes and respectively output electric signals corresponding to light irradiating the respective photodiodes. Each pixel PX outputs an electric signal corresponding to the light irradiating the pixel PX to the signal line selecting circuit 21 as a detection signal Vdet. In the present embodiment, the optical sensor 2 detects biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line driving circuit 20.

The gate line driving circuit 20 and the signal line selecting circuit 21 are provided in the frame area PA. Specifically, the gate line driving circuit 20 is provided in an area extending along the extending direction (second direction Dy) of a signal line SGL in the frame area PA. The signal line selecting circuit 21 is provided in an area extending along the extending direction (first direction Dx) of a gate line GCL in the frame area PA and is provided between the sensor unit 10 and the bending area BA.

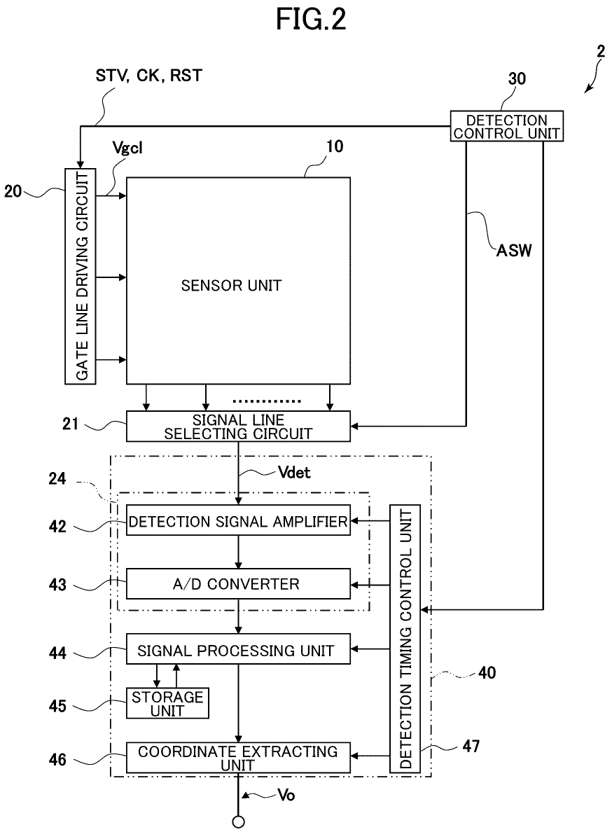

FIG. 2 is a block diagram showing an example of a configuration of the optical sensor according to the embodiment of the present invention. As shown in FIG. 2, the optical sensor 2 further includes a detection control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line driving circuit 20, the signal line selecting circuit 21, and the detection unit 40, and controls these operations. The detection control unit 30 supplies control signals, such as a start signal STV, a clock signal CK, and a reset signal RST, to the gate line driving circuit 20. The detection control unit 30 supplies control signals, such as a selection signal ASW, to the signal line selecting circuit 21.

The gate line driving circuit 20 drives the gate line GCL based on the control signals. The gate line driving circuit 20 sequentially or simultaneously selects a plurality of gate lines GCL, and supplies a gate drive signal Vgcl to the selected gate line GCL. In this manner, the gate line driving circuit 20 selects a pixel PX connected to the gate line GCL.

The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end circuit (AFE), for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detected signal amplifier 42 into a digital signal.

The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24.

The storage unit 45 temporarily stores the signal calculated by the signal processing unit 44. The storage unit 45 may be a random access memory (RAM) or a register circuit, for example.

The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

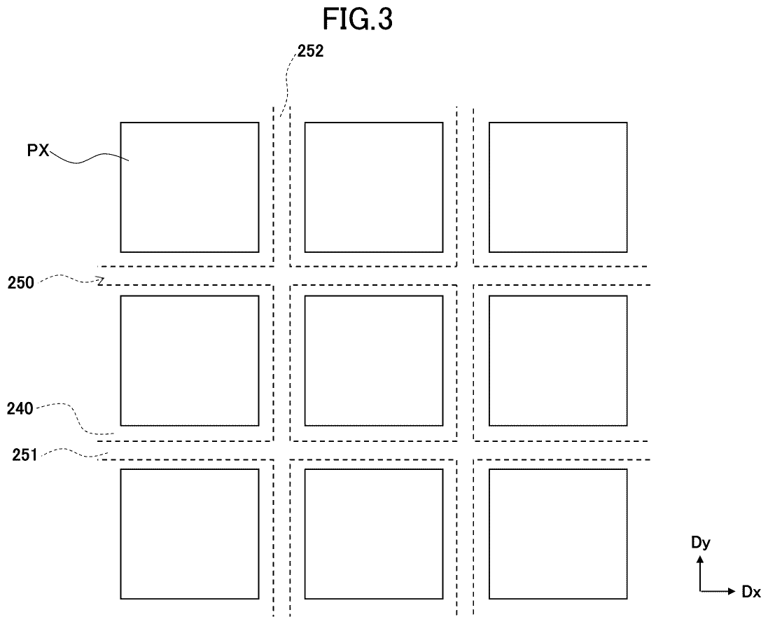

FIG. 3 is an enlarged plan view of the area A surrounded by the broken line in FIG. 1. The pixels PX are arranged in a matrix so as to be adjacent to one another. A carrier mobility reducing part 250 is provided between the pixels PX adjacent to each other. As will be described later, specifically, the carrier mobility reducing part 250 is provided between electrode covering parts 240 adjacent to each other. The carrier mobility reducing part 250 reduces a leakage current generated between adjacent pixels PX.

As shown in FIG. 3, the carrier mobility reducing part 250 includes a first carrier mobility reducing part 251 extending in the row direction (in this case, first direction Dx) of the pixels PX, and a second carrier mobility reducing part 252 extending in the column direction (in this case, second direction Dy) of the pixels PX in a plan view. The first carrier mobility reducing part 251 and the second carrier mobility reducing part 252 intersect each other so as to surround the pixels PX in a plan view. That is, the carrier mobility reducing part 250 has a grid shape that surrounds each of the pixels PX in a plan view.

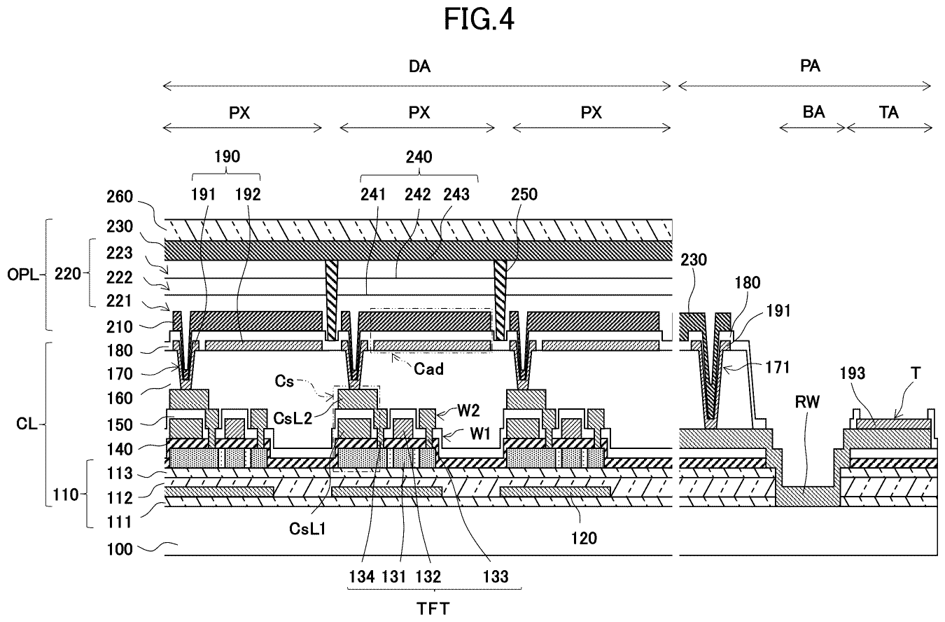

FIG. 4 is a partial sectional view of the optical sensor 2 taken along the line IV-IV of FIG. 1 according to the first embodiment. In FIG. 4, a part of the display area DA and a part of the frame area PA are shown in a cross-sectional view. As described above, the display area DA includes a plurality of pixels PX, and the frame area PA includes the bending area BA and the terminal area TA. Each pixel PX has one corresponding lower electrode 210 and one corresponding thin film transistor TFT.

FIG. 4 shows the resin substrate 100, a circuit layer CL, an organic photoelectric conversion layer OPL, and a sealing film 260, which are laminated in a cross-sectional view. The circuit layer CL includes layers from a barrier inorganic film 110 to an inorganic insulating film 180, and the organic photoelectric conversion layer OPL includes layers from a lower electrode 210 to an upper electrode 230.

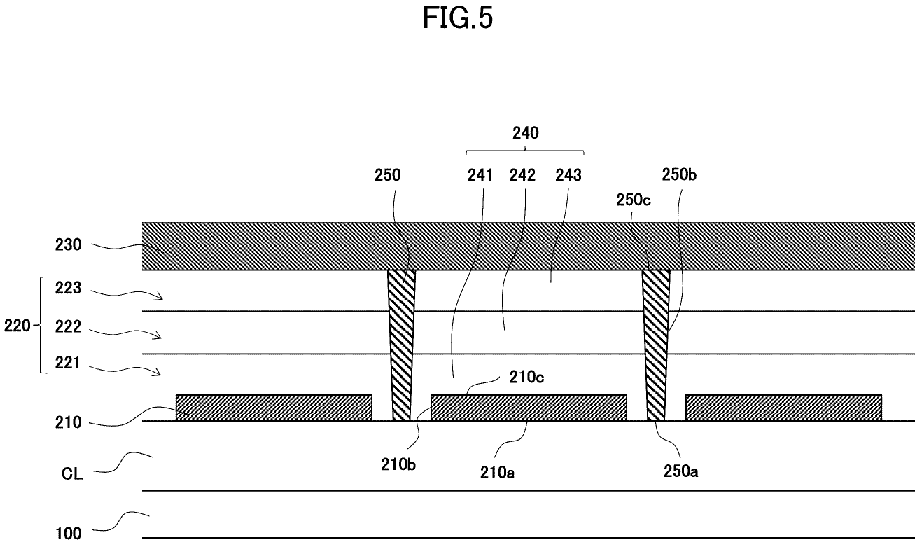

FIG. 4 shows the cut surface in the second direction Dy, although the cut surface in the first direction Dy has the similar cross-sectional configuration as that in FIG. 4 in the display area DA. In FIG. 4, hatching of some layers is omitted for clarity of the cross-sectional structure (the same applies to FIGS. 5 to 6A, 8 to 10A).

In the following, the laminated structure of layers from the resin substrate 100 to the sealing film 260 will be described in order from the lower layer. First, the circuit layer CL provided on the resin substrate 100 will be described.

A barrier inorganic film 110 is laminated on the resin substrate 100. The resin substrate 100 is made of polyimide. However, any resin material may be used if the substrate has sufficient flexibility as the sheet-type optical sensor. The barrier inorganic film 110 has a three-layered structure of a first inorganic film (e.g., silicon oxide film) 111, a second inorganic film (e.g., silicon nitride film) 112, and a third inorganic film (e.g., silicon oxide film) 113. The first inorganic film 111 is provided to improve the adhesion to the substrate, the second inorganic film 112 is provided to block moisture and impurities from the outside, and the third inorganic film 113 is provided to prevent hydrogen atoms contained in the second inorganic film 112 from diffusing to the semiconductor layer 131, but the structure is not particularly limited thereto. The structure may include an additional layer, or may be formed of one layer or two layers.

An additional film 120 may be formed at a portion where the thin film transistor TFT to be described later is formed. The additional film 120 reduces a change in characteristics of the thin film transistor TFT due to penetration of light from the back surface of the channel of the thin film transistor TFT or provides a predetermined potential by being formed of a conductive material, thereby providing a back gate effect to the thin film transistor TR. Here, after the first inorganic film 111 is formed, the additional film 120 is formed in an island shape in accordance with the portion where the thin film transistor TFT is formed, and then the second inorganic film 112 and the third inorganic film 113 are laminated, and the additional film 120 is thereby sealed in the barrier inorganic film 110. In this regard, the present invention is not limited thereto, and the additional film 120 may be first formed on the resin substrate 100 and then the barrier inorganic film 110 may be formed thereon.

A thin film transistor TFT is formed on the barrier inorganic film 110 for each pixel PX. The thin film transistor TFT includes a semiconductor layer 131, a gate electrode 132, a source electrode 133, and a drain electrode 134. In this case, a polysilicon thin film transistor is taken as an example, and only an N-channel transistor is shown, although a P-channel transistor may be simultaneously formed. The semiconductor layer 131 of the thin film transistor TFT has a structure in which a low-concentration impurity area or an intrinsic semiconductor area is provided between a channel area and a source/drain area. The gate electrode 132 is a portion where the gate line GCL is electrically connected to the semiconductor layer 131 in each pixel PX. Similarly, the source electrode 133 is a portion where the signal line SGL is electrically connected to the semiconductor layer 131 in each pixel PX.

A gate insulating 140 is provided between the semiconductor layer 131 and the gate electrode 132. In this case, a silicon oxide film is used as the gate insulating film 140. The gate electrode 132 is a part of the first wiring layer W1 formed of MoW. The first wiring layer W1 includes a first holding capacitance line CsL1 in addition to the gate electrode 132. A part of the holding capacitor Cs is formed between the first holding capacitance line CsL1 and the semiconductor layer 131 (source/drain regions) via the gate insulating film 140.

An interlayer insulating film 150 is formed on the gate electrode 132. The interlayer insulating film 150 has a structure in which a silicon nitride film and a silicon oxide film are laminated. The films from the barrier inorganic film 110 to the interlayer insulating film 150 are patterned and removed at the area corresponding to the bending area BA. The polyimide forming the resin substrate 100 is exposed in the area corresponding to the bending area BA. When the barrier inorganic film 110 is patterned to be removed, the surface of the polyimide may be partially eroded or lost.

A wiring pattern is formed under each of the step at the edge of the interlayer insulating film 150 and the step at the edge of the barrier inorganic film 110. A routing wire RW to be formed in the next process is disposed over the wiring pattern when crossing the steps. For example, the gate electrode 132 is disposed between the interlayer insulating film 150 and the barrier inorganic film 110, and the additional film 120 is disposed between the barrier inorganic film 110 and the resin substrate 100. As such, the wiring pattern is formed using these layers.

A second wiring layer W2, which includes the source electrode 133, the drain electrode 134, and a portion serving as the routing wire RW, is formed on the interlayer insulating film 150. In this case, a three-layered structure of Ti, Al, and Ti is employed. The first holding capacitance line CsL1 (a part of the first wiring layer W1) and the second holding capacitance line CsL2 (a part of the second wiring layer W2) form another part of the holding capacitor Cs via the interlayer insulating film 150. The routing wire RW extends to the terminal area TA via the bending area BA and forms a terminal portion T to which the flexible printed substrate 300 is connected, for example.

The routing wire RW is formed so as to reach the terminal portion T across the bending area BA, and thus crosses the steps of the interlayer insulating film 150 and the barrier inorganic film 110. As described above, the wiring pattern formed by the additional film 120, for example, is formed in the steps. As such, even if the routing wire RW is disconnected at the recess of the step, the electrical connection can be maintained by contacting the wiring pattern.

A flattening film 160 is disposed so as to cover the source electrode 133, the drain electrode 134, and the interlayer insulating film 150. The flattening film 160 is made of resin, such as photosensitive acryl, because such a material is superior in surface flatness to an inorganic insulating material formed by CVD (chemical vapor deposition), for example. The flattening film 160 is removed in a pixel contact portion 170, an upper electrode contact portion 171, the bending area BA, and the terminal area TA.

A transparent conductive film 190 made of indium tin oxide (ITO) is formed on each pixel PX on the flattening film 160. The transparent conductive film 190 includes a first transparent conductive film 191 and a second transparent conductive film 192, which are separated from each other.

In the pixel contact portion 170, the first transparent conductive film 191 covers the second wiring layer W2, a surface of which is exposed by removal of the flattening film 160. An inorganic insulating film (silicon nitride film) 180 is provided on the flattening film 160 so as to cover the first transparent conductive film 191. The inorganic insulating film 180 is open to the pixel contact portion 170.

The second transparent conductive film 192 is disposed below a lower electrode 210 (further below the inorganic insulating film 180) to be described later and next to the pixel contact portion 170. The second transparent conductive film 192, the inorganic insulating film 36, and the lower electrode 210 overlap one another and form an additional capacitance Cad.

A third transparent conductive film 193 may be formed on the surface of the terminal portion T. The third transparent conductive film 193 formed on the surface of the terminal portion T may be provided for the purposes of protecting the exposed wiring portion from a damage in a subsequent process.

The configuration of the circuit layer CL provided on the substrate 100 has been described. Next, the organic photoelectric conversion layer OPL provided on the circuit layer CL in the display area DA will be described. In the following, FIG. 5 will be referred to together with FIG. 4. FIG. 5 is an enlarged schematic partial sectional view of the OPL in FIG. 4.

A lower electrode 210 is provided for each pixel PX on the inorganic insulating film 180 so as to be electrically connected to the drain electrode 134 through the opening of the inorganic insulating film 180 in the pixel contact portion 170. Each lower electrode 210 has a bottom surface 210a in contact with the inorganic insulating film 180, a side surface 210b facing the adjacent lower electrode 210, and an upper surface 210c facing an upper electrode 230 to be described later. The lower electrode 210 is formed as a reflective electrode and has a three-layered structure of an indium zinc oxide film, an Ag film, and an indium zinc oxide film. An indium tin oxide film may be used instead of the indium zinc oxide film. The lower electrode 210 extends laterally from the pixel contact portion 170 and above the thin film transistor TFT.

An organic material layer 220 is disposed on the lower electrode 210. The organic material layer 220 includes, in order from the bottom, a lower carrier transport layer 221, an organic light-receiving layer 222, and an upper carrier transport layer 223. When the front surface irradiation structure is employed, the lower carrier transport layer 221 is a hole transport layer and the upper carrier transport layer 223 is an electron transport layer. When the back surface irradiation structure is employed, the lower carrier transport layer 221 is an electron transport layer and the upper carrier transport layer 223 is a hole transport layer. The organic light-receiving layer 222 may be formed by vapor deposition or by coating on a solvent dispersion. In this case, the organic light-receiving layer 222 is formed over the entire surface of the detection area DA, but not limited thereto.

The organic material layer 220 has an electrode covering part 240 for each pixel PX. Each electrode covering part 240 includes a first electrode covering part 241 included in the lower carrier transport layer 221, a second electrode covering part 242 included in the organic light-receiving layer 222, and a third electrode covering part 243 included in the upper carrier transport layer 223. The second electrode covering part 242 is provided so as to overlap the first electrode covering part 241, and the third electrode covering part 243 is provided so as to overlap the second electrode covering part 242.

The plurality of first electrode covering parts 241 each cover at least the upper surface 210c of the corresponding one of the lower electrodes 210 disposed adjacent to one another. The first electrode covering parts 241 each cover the upper surface 210c and the side surface 210b of the corresponding one of the lower electrodes 210 disposed adjacent to one another. On the other hand, the bottom surface 210a of the lower electrode 210 is in contact with the inorganic insulating film 180 and is not covered by the first electrode covering parts 241. The first electrode covering parts 241 may each cover only the upper surface 210c of the corresponding one of the lower electrodes 210 disposed adjacent to one another.

A carrier mobility reducing part 250 that reduces the carrier mobility between the adjacent first electrode covering parts 241 is provided between the adjacent first electrode covering parts 241. In the first embodiment, the carrier mobility reducing part 250 is disposed between adjacent electrode covering parts 240. In this manner, the carrier mobility reducing part 250 is provided between the first electrode covering parts 241 adjacent to each other, and this can reduce the leakage current generated between the lower electrodes 210 adjacent to each other via the lower carrier transport layer 221.

The carrier mobility reducing part 250 includes a bottom surface 250a, a side surface 250b, and an upper surface 250c. In the first embodiment, the bottom surface 250a of the carrier mobility reducing part 250 is in contact with the inorganic insulating film 180, the side surface 250b of the carrier mobility reducing part 250 is in contact with the electrode covering part 240, and the upper surface 250c of the carrier mobility reducing part 250 is in contact with the upper electrode 230. That is, the organic material layer 220 is not provided between the bottom surface 250a of the carrier mobility reducing part 250 and the inorganic insulating film 180, and between the upper surface 250c of the carrier mobility reducing part 250 and the upper electrode 230. Such a configuration enables the organic layer 220 to be physically and electrically separated for each pixel PX, and the leakage current between the pixels PX can be thereby reduced more reliably.

If the leakage current between adjacent pixels PX can be reduced by the carrier mobility reducing part 250, the organic layer 220 may be provided between the bottom surface 250a of the carrier mobility reducing part 250 and the inorganic insulating film 180.

The side surface 250b of the carrier mobility reducing part 250 may be in contact with the side surface 210b of the lower electrode 210 based on the premise that the first electrode covering parts 241 covers only the upper surface 210c of the corresponding one of the lower electrodes 210 adjacent to one another.

The upper electrode 230 is formed in common to the pixels PX on the organic material layer 220. When the front surface irradiation structure is employed, the upper electrode 230 needs to be transparent. Here, PEDOT: PSS is formed on the surface in contact with the organic material layers 220, and then the upper electrode 230 is formed using a metallic material, such as Ag and Al, as a thin film that allows incident light to transmit. The upper electrode 230 is formed over the organic material layer 220 disposed on the detection area DA and the upper electrode contact portion 171 disposed on the frame area PA. The upper electrode 230 is electrically connected to the routing wire RW of the second wiring layer W2 in the upper electrode contact portion 171, and eventually extracted to the terminal portion T.

A sealing film 260 is formed on the upper electrode 140. One of the functions of the sealing film 260 is to protect the organic material layer 220 from moisture entering from the outside, and is required to have a high gas barrier property. Here, the sealing film 260 has a laminate structure including a silicon nitride film, and includes a silicon nitride film, an organic resin, and a silicon nitride film. A silicon oxide film or an amorphous silicon layer may be provided between the silicon nitride film and the organic resin to improve adhesion. However, such a film is provided on the light-receiving surface side, it is thus preferable that the materials do not absorb or otherwise act on light of the wavelength to be detected.

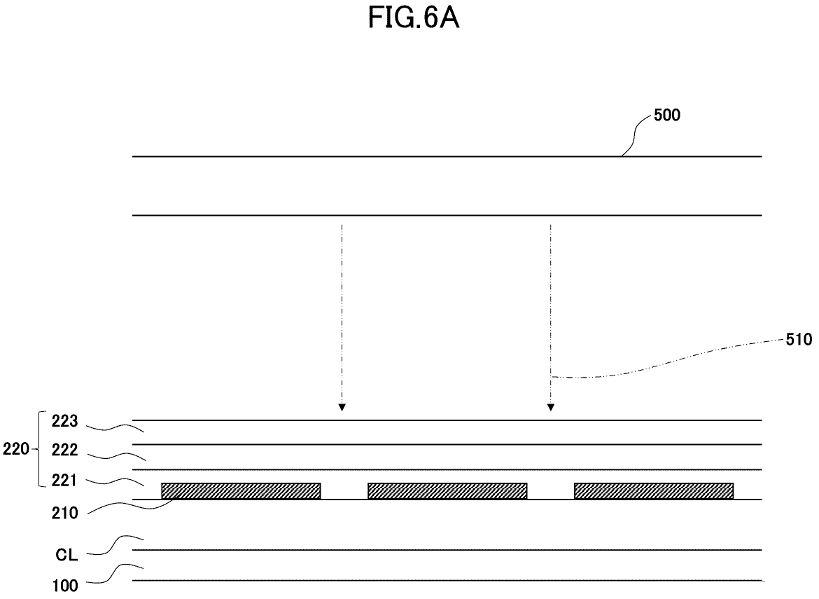

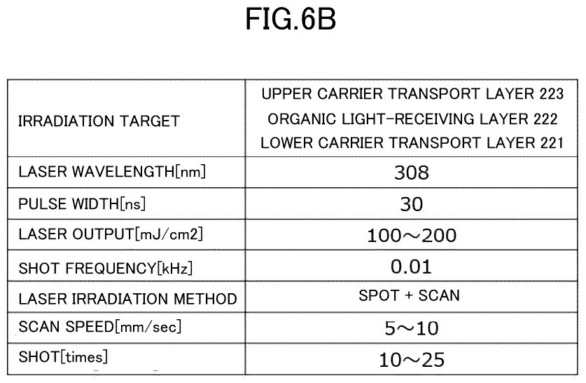

Next, a process of forming the carrier mobility reducing part 250 according to the first embodiment will be described. FIG. 6A is a schematic cross section showing a process of forming the carrier mobility reducing part 250 according to the first embodiment. FIG. 6B is a table showing an example of laser conditions to be used when the carrier mobility reducing part 250 according to the first embodiment is formed. In the example shown in FIG. 6A, a laser beam 510 is irradiated from the light source device 500 onto the organic material layer 220 so as to remove a part of the organic material layer 220 between the lower electrodes 210 adjacent to each other. In this process, the electrode covering part 240 is formed for each pixel PX in the organic material layer 220.

In a case where a distance between adjacent lower electrodes 210 is too short, even if such a part is removed, a leakage current may be generated depending on the material of the organic material layer 220. As such, a distance between adjacent lower electrodes 210 may desirably be wide to some extent (e.g., 30 μm). When the accuracy is considered, the laser patterning is preferably performed at approximately 20 μm or less, for example.

After the laser patterning, a material is applied between the adjacent electrode covering parts 240, and a coating layer thereby obtained is cured so as to form the carrier mobility reducing part 250. The material may be applied using any suitable method, such as an ink jet method and a screen printing method.

The material for forming the carrier mobility reducing part 250 may have a lower carrier mobility than at least the material for forming the lower carrier transport layer 221. Carrier mobility is a physical quantity indicating ease of transfer of carriers (electrons or holes) in a material. In the organic material layer 220, the carrier mobility of the organic light-receiving layer 222 is lower than that of the lower carrier transport layer 221 and the upper carrier transport layer 223. In the first embodiment, the carrier mobility reducing part 250 is formed of a material that is different from the material of the organic material layers 220 (e.g., an insulating material such as polyimide).

In the process described above, the carrier mobility reducing part 250 is formed by laser patterning without using a mask, although laser patterning using a mask in a line scan is more preferable in view of accuracy. As such, in the following, the carrier mobility reducing part 250 formed by laser patterning using a mask will be described.

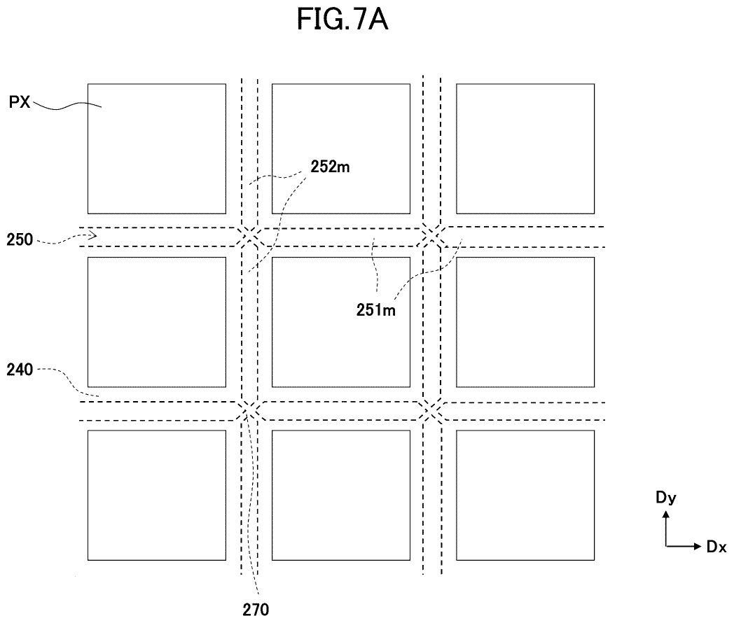

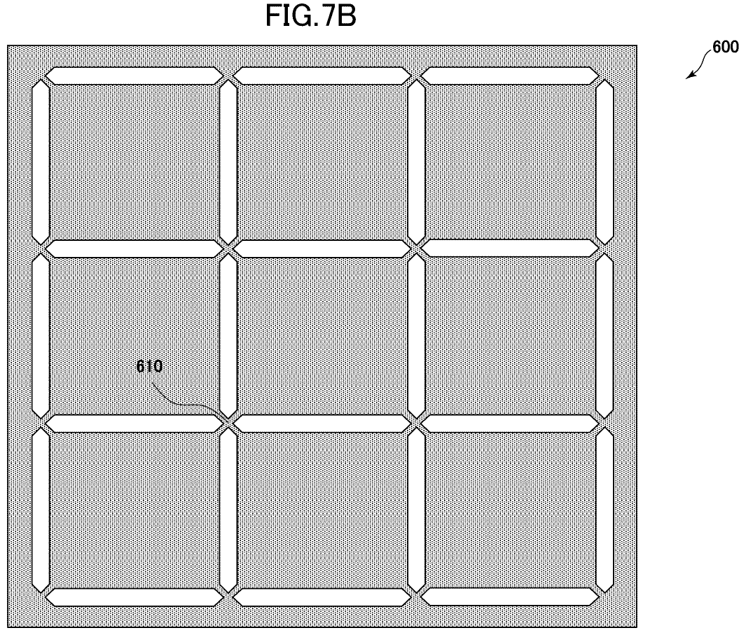

FIG. 7A is another example of an enlarged plan view of the area A enclosed by the broken line in FIG. 1. Specifically, FIG. 7A is an enlarged plan view of the area A when the carrier mobility reducing part 250 is formed by laser patterning using a mask. FIG. 7B is a schematic diagram illustrating an example of a film forming mask used in a process of forming the carrier mobility reducing part 250.

In FIG. 7A, the carrier mobility reducing part 250 is partially provided along the direction in which the edge of the lower electrode 210 extends in a plan view. In an example shown in FIG. 7A, one of the directions in which the edge of the lower electrode 210 extends is the row direction of the pixels PX (here, first direction Dx), and the other of the directions in which the edge of the lower electrode 210 extends is the column direction of the pixels PX (here, second direction Dy). That is, in the example shown in FIG. 7A, the carrier mobility reducing part 250 includes a plurality of first carrier mobility reducing parts 251m provided along the first direction Dx and a plurality of second carrier mobility reducing parts 252m provided along the second direction Dy.

Bridges 270 are provided between adjacent first carrier mobility reducing parts 251m and adjacent second carrier mobility reducing parts 252m. The bridge 270 is inevitably formed during the laser patterning using a mask. That is, as shown in FIG. 7B, the film forming mask 600 structurally includes a non-irradiated part 610 between the respective parts corresponding to the electrode covering parts 240. The part corresponding to the non-irradiated part 610 of the organic material layer 220 is not irradiated with the laser beam, and thus the bridge 270 is formed. The shape and arrangement of the bridges 270 are not limited to the example shown in FIG. 7A, and may be changed depending on the shape and arrangement of the non-irradiated part of the film-forming mask to be used. For the viewpoint of reducing the leakage current between the pixels PX, it is preferable to arrange the bridges 270 at the corners of the pixel PX.

### Second Embodiment

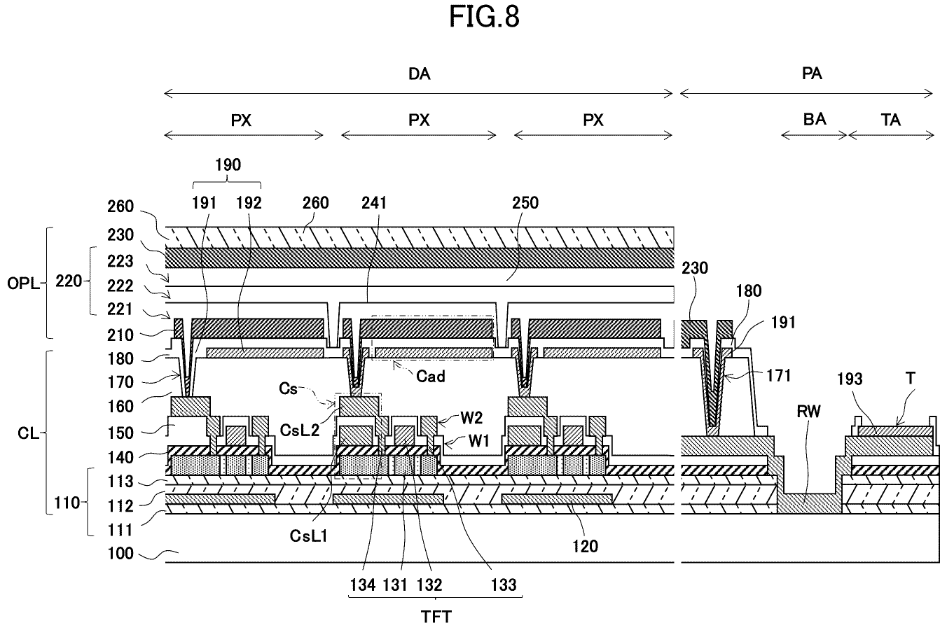

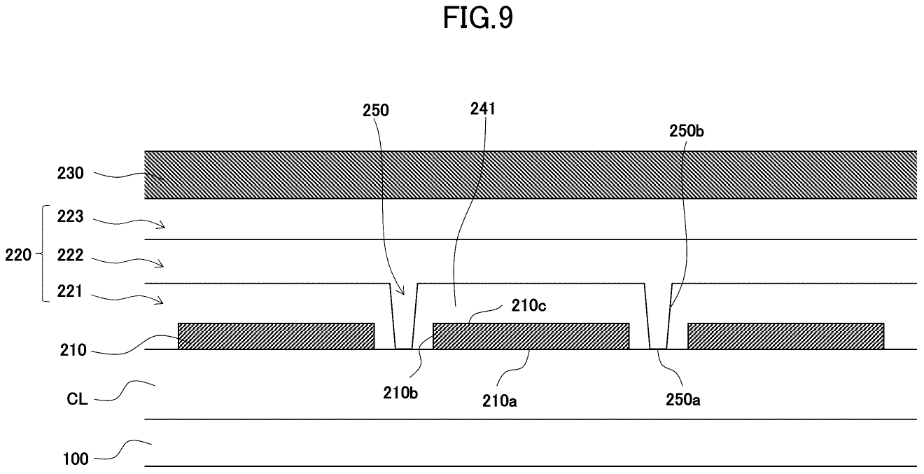

Finally, the second embodiment will be discussed. FIG. 8 is a partial sectional view of the optical sensor 2 taken along the line IV-IV of FIG. 1 according to the second embodiment. FIG. 9 is an enlarged schematic partial sectional view of the OPL and its surroundings shown in FIG. 8. The same configuration as that of the first embodiment will not be described.

As shown in FIG. 8, the configuration from the substrate 100 to the lower electrode 210 and the configuration from the upper electrode 230 to the sealing film 260 are the same as those of the first embodiment. Similarly to the first embodiment, the organic layer 220 is also disposed on the lower electrode 210.

On the other hand, the second embodiment is different from the first embodiment in that the organic light-receiving layer 222 and the upper carrier transport layer 223 are formed in common to the pixels PX on the lower carrier transport layer 221. As such, in the second embodiment, the organic light-receiving layer 222 does not include the second electrode covering part 242, and the upper carrier transport layer 223 does not include the third electrode covering part 243.

The second embodiment is also different from the first embodiment in that a part of the organic light-receiving layer 222, which is the upper layer of the lower carrier transport layer 221, constitutes the carrier mobility reducing part 250. As described above, the carrier mobility of the organic light-receiving layer 222 is lower than that of the lower carrier transport layer 221. As such, even if a part of the organic light-receiving layer 222 constitutes the carrier mobility reducing part 250, a leakage current generated between the adjacent lower electrodes 210 via the lower carrier transport layer 221 can be reduced. Such a configuration can eliminate the need of separating the process of forming the organic light-receiving layer 222 from the process of forming the carrier mobility reducing part 250, and thus it is possible to reduce the leakage current between adjacent pixels PX without lowering the productivity.

In the second embodiment, the carrier mobility reducing part 250 formed by a part of the organic light-receiving layer 222 is provided between the first electrode covering parts 241 adjacent to each other. In this regard, the bottom surface 250a of the carrier mobility reducing part 250 is in contact with the inorganic insulating film 180, and the side surface 250b of the carrier mobility reducing part 250 is in contact with the first electrode covering part 241. That is, the organic material layer 220 is not provided between the bottom surface 250a of the carrier mobility reducing part 250 and the inorganic insulating film 180. Such a configuration enables the lower carrier transport layers 221 to be physically and electrically separated for each pixel PX, and the leakage current between pixels PX can be thereby reduced more reliably.

If the leakage current between adjacent pixels PX can be reduced by the carrier mobility reducing part 250, the lower carrier transport layer 221 may be provided between the bottom surface 250a of the carrier mobility reducing part 250 and the inorganic insulating film 180.

The side surface 250b of the carrier mobility reducing part 250 may be in contact with the side surface 210b of the lower electrode 210 based on the premise that the first electrode covering parts 241 covers only the upper surface 210c of the corresponding one of the lower electrodes 210 adjacent to one another.

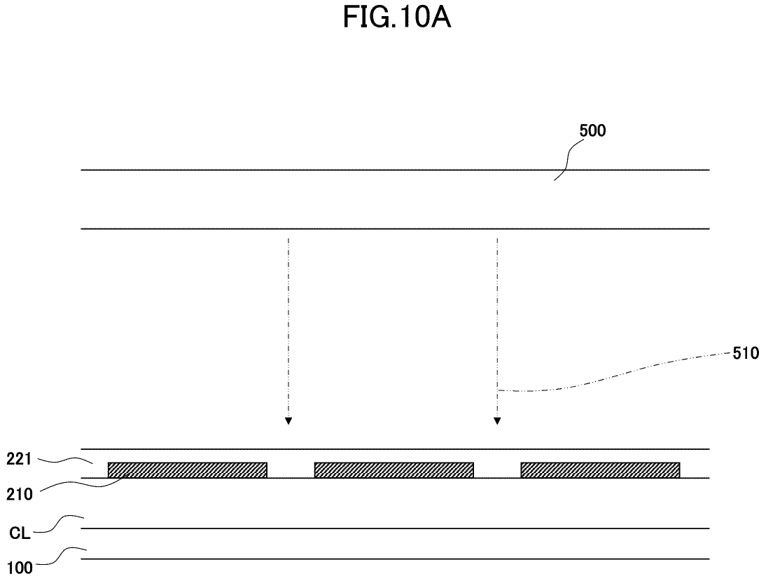

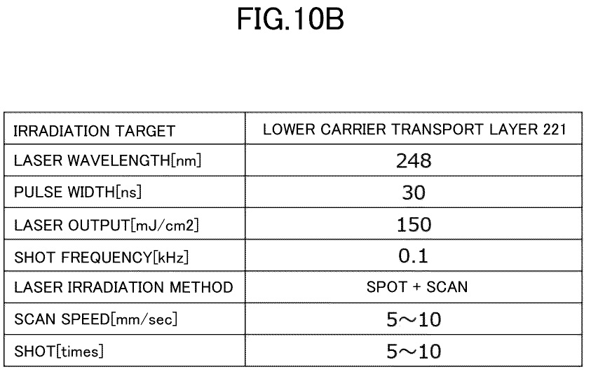

Finally, a process of forming the carrier mobility reducing part 250 according to the second embodiment will be described. FIG. 10A is a schematic cross section showing a step of forming the carrier mobility reducing part 250 according to the second embodiment. FIG. 10B is a table showing an example of laser conditions to be used when the carrier mobility reducing part 250 according to the second embodiment is formed. The present embodiment is different from the first embodiment in that the lower carrier transport layer 221 is formed on the circuit layer CL, and then laser patterning is performed before the organic light-receiving layer 222 and the upper carrier transport layer 223 are formed. The laser patterning is performed in the same manner as that of the first embodiment, and thus will not be described. After the laser patterning, the organic light-receiving layer 222 is applied to the entirety of the lower carrier transport layer 221 and the obtained coated layer is cured, whereby the carrier mobility reducing part 250 is formed between the adjacent first electrode covering parts 241.

In the second embodiment as well, similarly to the first embodiment as described in FIG. 7A, the laser patterning using a mask may be performed to partially provide the carrier mobility reducing part 250 along the direction in which the edge of the lower electrode 210 extends in a plan view.

As a modification, the carrier mobility reducing part 250 may be configured such that the first embodiment and the second embodiment are combined. That is, the carrier mobility reducing part 250 may be constituted by a material having a lower carrier mobility than at least the material forming the lower carrier transport layer 221 (e.g., insulating material such as polyimide) together with a part of the organic light-receiving layer 222.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An optical sensor comprising:
a plurality of lower electrodes;
an organic material layer that includes a lower carrier transport layer including a plurality of first electrode covering parts each covering at least an upper surface of corresponding one of the plurality of lower electrodes; and
a carrier mobility reducing part that is provided in at least a part of an area between the adjacent first electrode covering parts so as to reduce carrier mobility of the adjacent first electrode covering parts.

2. The optical sensor according to claim 1, wherein
the first electrode covering part covers a side surface of the lower electrode.

3. The optical sensor according to claim 1, wherein
the carrier mobility reducing part is partially provided along a direction in which an edge of the lower electrode extends in a plan view.

4. The optical sensor according to claim 1, wherein
the carrier mobility reducing part is formed of a material that is different from a material of the organic material layer and has a lower carrier mobility than at least a material of the lower carrier transport layer.

5. The optical sensor according to claim 1, wherein
the organic material layer further includes an organic light receiving layer including a plurality of second electrode covering parts respectively overlapping the first electrode covering parts, and
the carrier mobility reducing part is disposed between the adjacent second electrode covering parts.

6. The optical sensor according to claim 5, wherein
the organic material layer further includes an upper carrier transport layer including a plurality of third electrode covering parts respectively overlapping the second electrode covering parts, and
the carrier mobility reducing part is disposed between the adjacent third electrode covering parts.

7. The optical sensor according to claim 1, wherein
the organic material layer further includes an organic light receiving layer provided on the lower carrier transport layer, and
a part of the organic light receiving layer constitutes the carrier mobility reducing part.
